(19) United States
(12) Patent Application Publication
(10) Pub. No.: US 2007/0287251 A1
(43) Pub. Date: Dec. 13, 2007

(54) Method for forming a memory device with at least one memory cell, in particular a phase change memory cell, and memory device

(76) Inventor: Ulrike Gruening-von Schwerin, Munchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/449,050

(22) Filed: Jun. 8, 2006

(51) Int. Cl. H01L 21/336

(52) U.S. Cl. 438/257

(57) ABSTRACT

A method for forming a memory device with at least one memory cell, the memory cell including a volume of switching active material is disclosed. The method includes the process of depositing a first layer of insulating material on a substrate, depositing a layer of switching active material on the layer of insulating material, patterning the layer of switching active material to form volumes of switching active material. A second layer of insulating material is deposited. Vias are formed in the layers of the first insulating material, the switching active material and the second layer of insulating material in one method process. The vias are filled with a conductive material to form first and second electrode contacts for electrically coupling the volumes of switching active material. Furthermore the invention relates to a memory device produced by using this method.

### BACKGROUND

The invention relates to a method for forming a memory device with at least one memory cell, in particular a phase change memory cell, and to a memory device.

### FIELD OF THE INVENTION

Conventional memory devices, in particular semiconductor memory devices, can be differentiated into a first group of functional memory devices, e.g. PLAs, PALs, etc, a second group of table memory devices, e.g. ROM devices such as PROMs, EPROMs, EEPROMs, flash memories, etc. Furthermore there is a third group of RAM devices, such as DRAMs and SRAMs.

Further, the memory devices can be divided into volatile and non-volatile memory devices.

For example, in the case of SRAM (SRAM=Static Random Access Memory), the individual memory cells consist of few, for instance of 6, transistors, and in the case of DRAMs (DRAM=Dynamic Random Access Memory) usually only of one single, correspondingly controlled capacitive element, e.g. a selection transistor coupled to a capacitor, wherein one bit can be stored as charge.

As the charge in the capacitance of a DRAM memory cell remains for a short time only, it must be refreshed regularly, e.g. a “refresh” is performed approximately every 64 ms.

In contrast to that in the case of SRAMs the data stored in the memory cell remain stored as long as an appropriate supply voltage is supplied so that the transistors do not lose their switching state.

However, DRAMs as well as SRAMs are volatile memories which loose their data at least when the supply voltage is switched off.

In the case of non-volatile memory devices (NVMs), such as EPROMs, EEPROMs or flash memories, the stored data remain stored in a memory cell even when the supply voltage is switched off.

Recently so called “resistive” or “resistively switching” memory devices have also become known, e.g. so called Phase Change Memories (“PCMs”).

In a “resistive” or “resistively switching” memory cell, an “active” or “switching active” material, which usually is positioned between two suitable electrodes, i.e. an anode and a cathode, can be switched between a conductive and a less conductive state by an appropriate switching process. The conductive state can be assigned a logic one and the less conductive state can be assigned a logic zero, or vice versa, which may, for instance, correspond to the logic arrangement of a bit.

For phase change memories (PCRAMs), for instance, an appropriate chalcogenide compound, for example Ge—Sb—Te (GST) or an In—Sb—Te compound, may be used as a “switching active” material that is positioned between two corresponding electrodes. This “switching active”, e.g. the chalcogenide material, can be switched between an amorphous and a crystalline state, wherein the amorphous state is the relatively weakly conducting state, which accordingly can be assigned a logic zero, and the crystalline state, i.e. a relatively strongly conductive state, accordingly can be assigned a logic one. In the following this material will be referred to as the switching active material.

To achieve a change from the amorphous, i.e. a relatively weakly conductive state of the switching active material, to a crystalline, i.e. a relatively strongly conductive state, the material has to be heated. For this purpose a heating current pulse is sent through material which heats the switching active material beyond its crystallization temperature thus lowering its resistance. In this way the value of a memory cell can be set to a first logic state.

Vice versa, the switching material can be heated by applying a relatively high current to the cell which causes the switching active material to melt and by subsequently “quench cooling” the material can brought into an amorphous, i.e. relatively weakly conductive state, which may be assigned a second logic state, that is to reset the first logic state.

Various concepts have been proposed for PCRAM cells, for example the mushroom cell is known from S. J. Ahn, “Highly Manufacturable High Density Phase Change Memory of 64 MB and Beyond”, IEDM 2004, and H. Horii et al. “A novel cell technology using N-doped GeSbTe films for phase change RAM”, VLSI, 2003, and Y. N. Hwang et al “Full integration and reliability evaluation of phase-change RAM based on 0.24 um-CMOS technologies”, VLSI, 2003, and S. Lai et al “OUM—a 180 nm non-volatile memory cell element technology for stand alone and embedded applications”, IEDM 2001, or the edge contact cell by Y. H. Ha et al “An edge contact cell type cell for phase change RAM featuring very low power consumption”, VLSI, 2003 or the micro-trench cell by F. Pellizer et al, “Novel uTrench phase change memory cell for embedded and standalone non-volatile memory applications”, VLSI 2004.

Besides these cell designs a bridge cell design is known, which substantially—in a cross section through a corresponding semiconductor memory device—includes a vertically low but horizontally oblong volume of switching active material. The ends of the oblong volume of switching active material are each located on top of an electrode, thus forming a bridge between the electrodes.

One disadvantage of the currently known bridge cell type design is that it cannot be shrunk to 6 or 8F2 (F2=minimum feature size) cell sizes, as overlay tolerances could otherwise impact cell functionality. Also, there are parasitic resistances in the current path through the switching active, i.e. the phase change material, which are caused by a curved path of the current flow triggered by the geometry of the contact area between the phase change material and the electrodes. Furthermore the tungsten (W) electrode, which is chosen because of its good manufacturability has an unwanted effect on the thermal insulation of the cell.

FIG. 1 illustrates a cross sectional representation of two conventional bridge type PCRAM memory cells in a memory device. The cells are formed on a substrate 1, which includes a selection transistor 2a, 2b for each memory cell and transistor contacts 3a, 3b, each coupling a memory cell to a transistor 2a, 2b. Further the transistors 2a, 2b are coupled to a ground line 4. The gaps between these functional elements are filled with an isolator 5, for example SiO2. The functions and co-operation of these and further components of the substrate are known to those skilled in the art.

The memory cells are formed on top of the surface of the transistor contacts 3a, 3b and the isolating material 5 fills the gaps between the transistor contacts 3a, 3b. For each memory cell a first electrode contact 6a, 6b is formed on top of transistor contact 3a, 3b. In the same layer a second electrode contact 7 is formed, which is located between the first electrode contacts 6a, 6b and which serves as a second electrode contact for the switching active material 8a, 8b of two adjacent memory cells, thus forming a shared top electrode contact for the two adjacent memory cells. The gap between the first electrode contacts 6a, 6b, i.e. the bottom electrodes, and the shared second electrode contact 7, i.e. the top electrode contact for both cells, is filled with an isolator. Both the first electrode contacts 6a and 6b as well as the second—shared—electrode contact 7 can be made of tungsten.

The switching active, i.e. the phase change material 8a, 8b, for a cell is then deposited on top of that surface such that it contacts a first electrode contact 6a or 6b respectively at its one end and the second electrode contact 7 at its other end. The second electrode contact 7 is coupled via a VO contact 9 to a bit line 10, which usually is a metal.

The switching active, i.e. the phase change material 8a, 8b, is thus contacted at one side, in this embodiment at the bottom side. Thus a current, which will flow through the material 8a, 8b when reading or writing the cell enters and leaves the material on one side. This causes the path of the current flow to be curved and thus causes parasitic resistances.

Also the tolerances involved when overlaying and etching the switching active material and—later on—the material of the VO connector do not allow to shrink the memory cell area to the minimum feature size of 6F2 or 8F2, because the tolerances could effect, that for example the VO connector is not exactly placed in the centre of shared electrode contact thus impacting the functionality of the memory cell.

Furthermore the use of tungsten for the electrode contacts degrades the thermal performance of the memory cell. As the thermal conductivity of tungsten is comparatively good the heat effected by the heating current pulse is lead away from the switching active material. Consequently the thermal conductance of tungsten has to be taken into account when dimensioning the magnitude of the current for writing the switching active material, i.e. to heat the switching active material for changing its resistivity.

For these and other reasons there is a need for the present invention.

### SUMMARY

The present invention provides a memory device, in particular a phase change memory device, and a method of making a memory device.

According to one embodiment of the invention there is provided a method of forming a memory device with a plurality of memory cells on top of a substrate, wherein the substrate provides first contacts for coupling a memory cell to a selection transistor, each memory cell including a volume of switching active material, the method including the process of: depositing a first layer of insulating material on the substrate; depositing a layer of switching active material on the layer of insulating material; patterning the layer of switching active material to form pieces of switching active material; depositing a second layer of insulating material; forming vias in the layers of the first insulating material, the switching active material and the second layer of insulating material in one method step; and filling the vias with a conductive material to form first and second electrode contacts for electrically coupling the volumes of switching active material.

According to another embodiment of the invention there is provided a method of forming a memory device with a plurality of memory cells on top of a substrate, wherein the substrate provides first contacts for coupling a memory cell to a selection transistor, each memory cell comprising a volume of switching active material, the method including the process of depositing a first layer of insulating material on the substrate; depositing a layer of switching active material on the layer of insulating material; patterning the layer of switching active material to form volumes of switching active material; depositing a second layer of insulating material; forming vias in the first insulating material, the switching active material and the second layer of insulating material in one method step; depositing a layer of an electrically conductive, thermally isolating material on the substrate; depositing a layer of an electrically conductive material on the substrate to fill the gaps between the volumes of switching active material and to form first and second electrode contacts for electrically coupling the volumes of switching active material.

Another embodiment of the invention is directed at method for forming a memory device including a plurality of memory cells on a substrate defining a reference plane, wherein a memory cell includes a volume of switching active material and electrodes for coupling to the volume at interfaces, wherein the interfaces for coupling the volume of switching active material are formed after the switching active material has been deposited.

Furthermore the invention is directed to a memory device with a plurality of memory cells on a substrate defining a reference plane, each memory cell comprising a volume of switching active material having interfaces and electrodes for coupling to the volume at interfaces, the surface-normal of the interfaces being parallel to the reference plane, and wherein in the perpendicular direction to the reference plane the extent of the electrodes exceeds the extent of the interfaces of the volume of switching active material

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a schematic, cross sectional view of a conventional bridge type PCRAM memory cell.

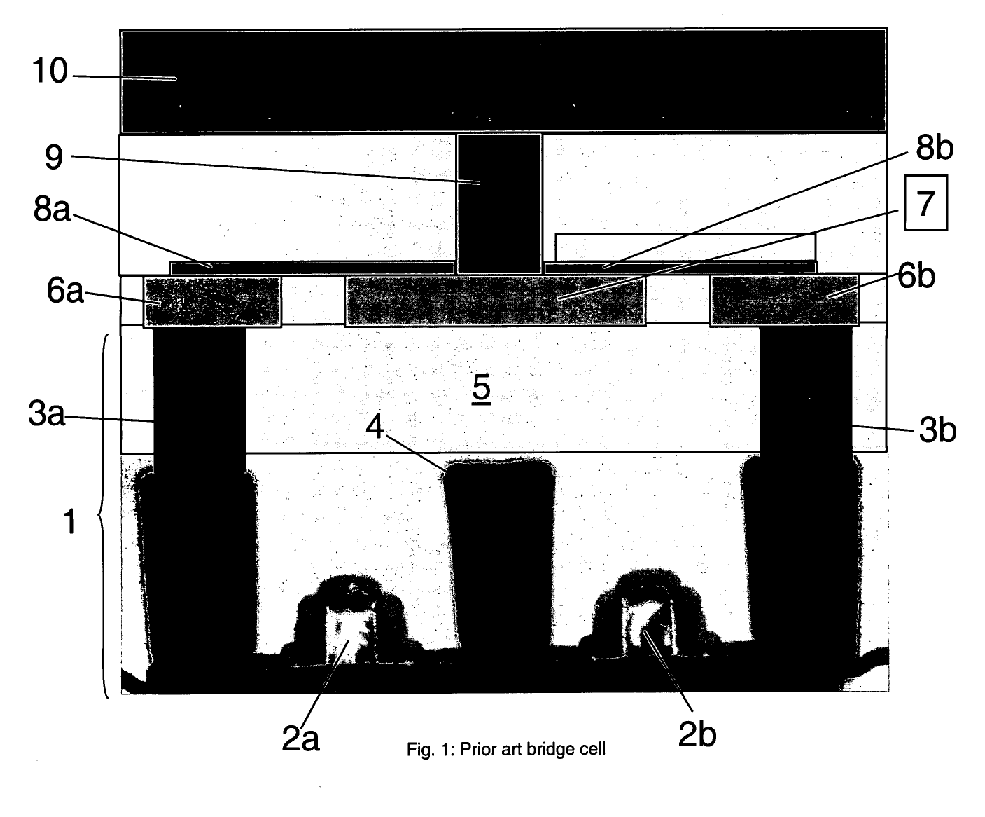

FIG. 2 is a cross sectional view illustrating a substrate on which memory cells will be created.

FIG. 3 is a view as in FIG. 2 after the deposition of first layers.

FIG. 4 is a view as in FIG. 3 after lithographic processing and etching.

FIG. 5 is the view as in FIG. 4 after forming electrode contacts.

FIG. 6 is a schematic cross sectional view through memory cells.

### DETAILED DESCRIPTION

In the following Detailed Description, reference is made to the accompanying drawings, which form a part hereof, and in which is illustrated by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a novel memory device with a plurality of memory cells, in particular phase change memory cells, and a corresponding method for forming such a device, in particular a method and a memory device which avoid the aforementioned drawbacks.

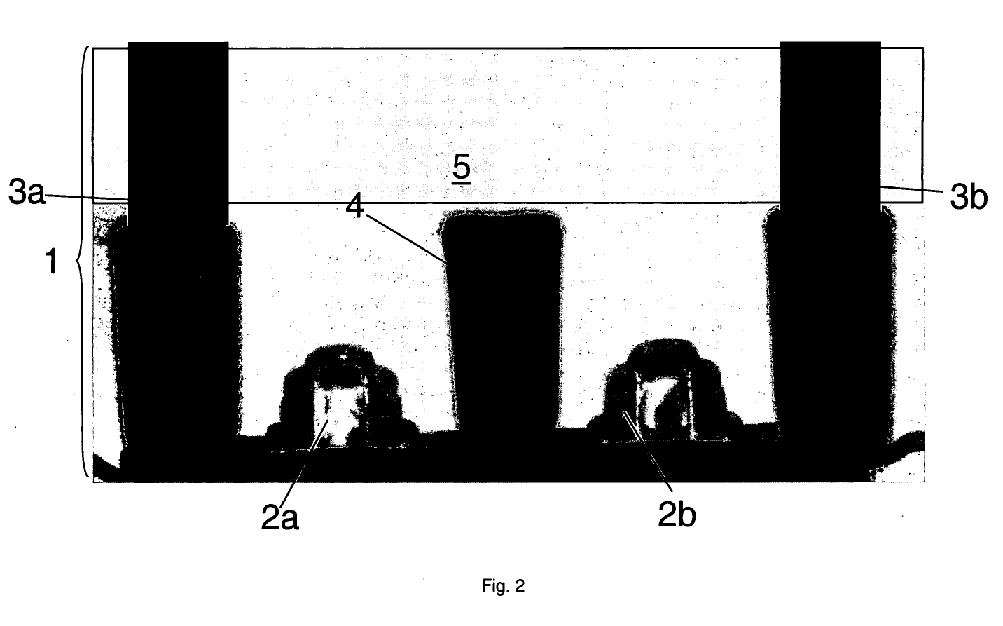

FIG. 2 illustrates a schematic cross sectional view of a substrate 1 onto which two memory cells will be formed. Up to this state the substrate 1 has been formed using conventional method processes. Embedded in the substrate 1 are two selection transistors 2a and 2b which will be used for selecting connected memory cells. The transistors 2a, 2b may be conventional transistors or transistors allowing the formation of borderless contacts. They are connected to transistor contacts 3a, 3b, which will be used each as a coupler to one electrode contact of a memory cell. The transistor contacts 3a, 3b can be of any conducting material, e.g. tungsten or polysilicon.

Also a ground line 4 of any conducting material, e.g. tungsten, is embedded in the substrate 1 to which the selection transistors 2a, 2b are coupled.

The interspaces between the described and other functional elements, which are well known to those skilled in the art and not illustrated in this view, are filled with insulating material, for example SiO2, so as to electrically insulate the elements against each other.

The surface of the substrate, onto which the following layers will be deposited and processed further on, is thus formed by the top surface of the transistor contacts 3a, 3b and the top surface of the insulating material 5.

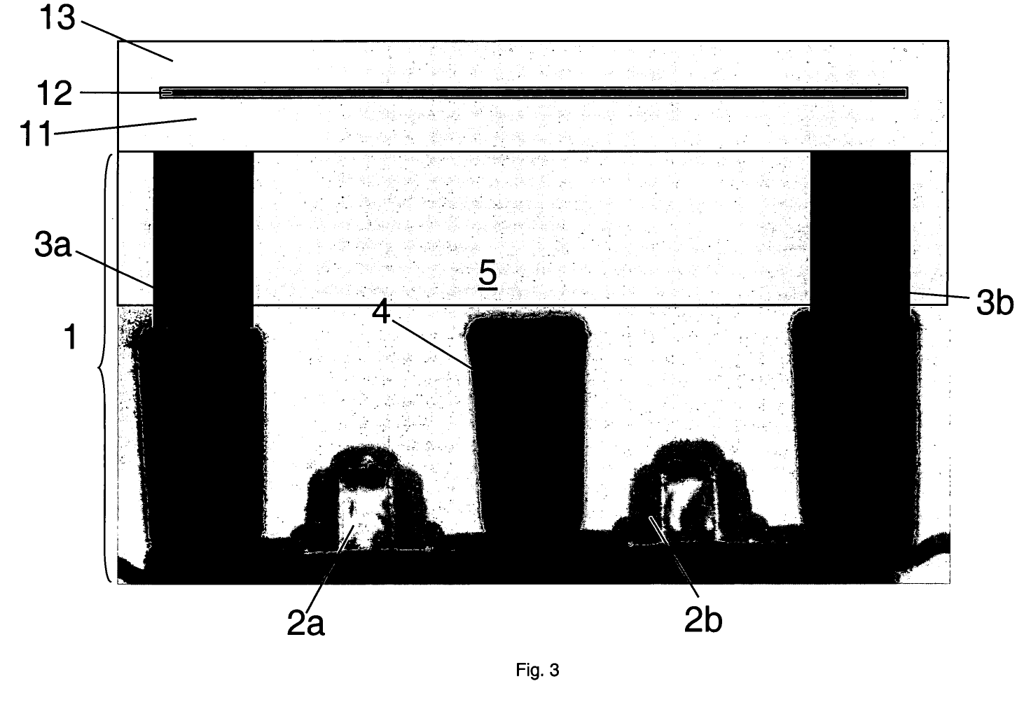

In FIG. 3 a cross sectional view at a later processing stage is represented. A first insulating layer 11 is deposited on the surface of the substrate 1. The layer may be deposited by using a conventional method such as chemical vapour deposition (CVD) and the thickness may be in the range of 5 to 200 nm, preferentially 20-50 nm.

This layer 11 will be used for forming insulating sockets for the volumes of switching active material. Thus the insulating layer may be of any insulating or semi-insulating material having a significant higher resistivity than the switching active material and preferentially a relatively low thermal conductivity. A suitable material may be an oxide, such as SiO2 or Al2O3, or SiN or any other suitable material, which may also be derived from a switching active material having a higher resistivity and a higher melting point than the switching active material itself.

On top of the insulating layer 11 a layer of switching active material 12 has been deposited by using a conventional method, such as CVD.

The thickness of this layer may range from 5 to 100 nm, depending on the minimum feature size. The switching active material may be a conventional chalcogenide such as a compound of Ge—Sb—Te (GST) or a compound of Ag—In—Sb—Te.

The volumes of switching active material in the memory cells to be produced will be formed from this layer of switching active material by using conventional lithographic and etching process later. So in order to improve the results of the lithographic and etching processes an optional layer of a material which serves as a hardmask material can be deposited on top of the layer of switching active material.

In the presently described preferred embodiment of the invention the optional layer of hardmask material is not illustrated. The layer can be deposited using a conventional process such as CVD. Any suitable material can be used as hardmask material and any suitable thickness of the layer can used. In the presently described preferred embodiment of the invention SiO2 would be suitable as hardmask material, which can be deposited with a thickness of approximately 40 nm.

In the following method process of lithographic processing and subsequently etching the layers of the optional hardmask material, the switching active material and the insulating layer material, the volumes of switching active material of the memory cells are patterned from the layer of switching active material 12. The etching process must be stopped at the latest when the surface of the transistor contacts 3a, 3b is reached. In this way either the volumes or lines of switching active material are formed, which will be patterned into volumes in a later method step. The volumes of switching active material may be shaped oblong in the direction parallel the surface of the substrate and have preferentially a length of 1 minimum feature size, whereas in the direction directed into the paper plane of the drawing the size of a volume of switching active material preferably is ½ to 1 of the minimum feature size.

After the layer of switching material 12 has been patterned a second layer of insulating material 13 is deposited to fill the gaps between volumes or lines of switching active material.

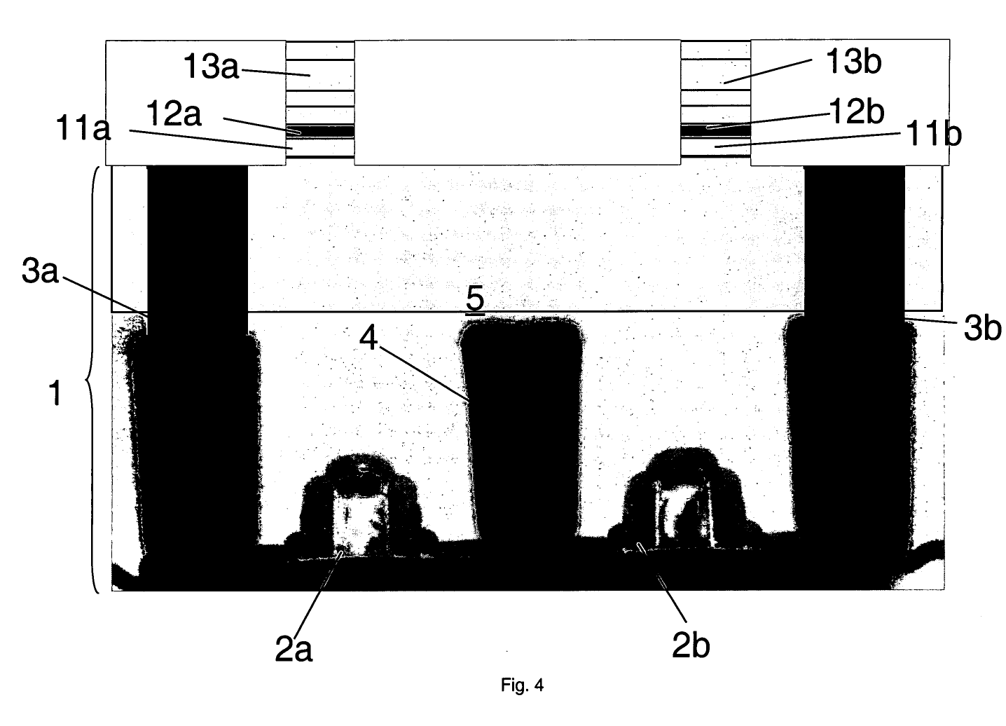

FIG. 4 represents a state in the production process after the lithographic processing and etching of vias has been performed. In the etching process, which can be a conventional etching process in which an optional hardmask layer can be used, the vias have been etched in the second layer of insulating material 13, the layer of switching active material 12 and the first layer of insulating material 11 in one method process.

As can be seen, in this preferred embodiment there are two volumes 12a, 12b of switching active material formed from a line or piece of switching active material 12, each being located on a socket 11a and 11b respectively of insulating material and covered by residual pieces of insulating material 13a, 13b and, if the optional hardmask material has been deposited, by residuals of the hardmask material.

Each via which is located above a contact 3a, 3b, is baring the contact. The horizontal, i.e. parallel to the surface of the substrate 1, extent of a via in this embodiment exceeds the horizontal extent of the underlying contact 3a, 3b. Although this is preferred other configurations are possible wherein the horizontal extent of a via is equal to or smaller than the horizontal extent of a contact 3a, 3b.

The vertical, i.e. perpendicular to the surface of the substrate 1, extent of a via not only exceeds the vertical extent of the switching active material, i.e. the thickness of the layer of switching active material 12. Instead the upper end of the via exceeds the upper end of the switching active material 12, so that the upper end of contact to be formed within a via exceeds the upper end of the switching active material.

As can be seen the dimension of the volumes of switching active material 12a, 12b in the horizontal direction—that is parallel to the surface of the substrate 1—is significantly larger than the thickness of the layer of switching active material 12 in this embodiment. The dimension of the volumes 12a, 12b in the remaining horizontal direction, which in the schematic drawing is into the paper plane, can be chosen accordingly so as to form oblong volumes of switching active material. According to the chosen cross sectional view of the drawings this dimension is not illustrated in the drawings.

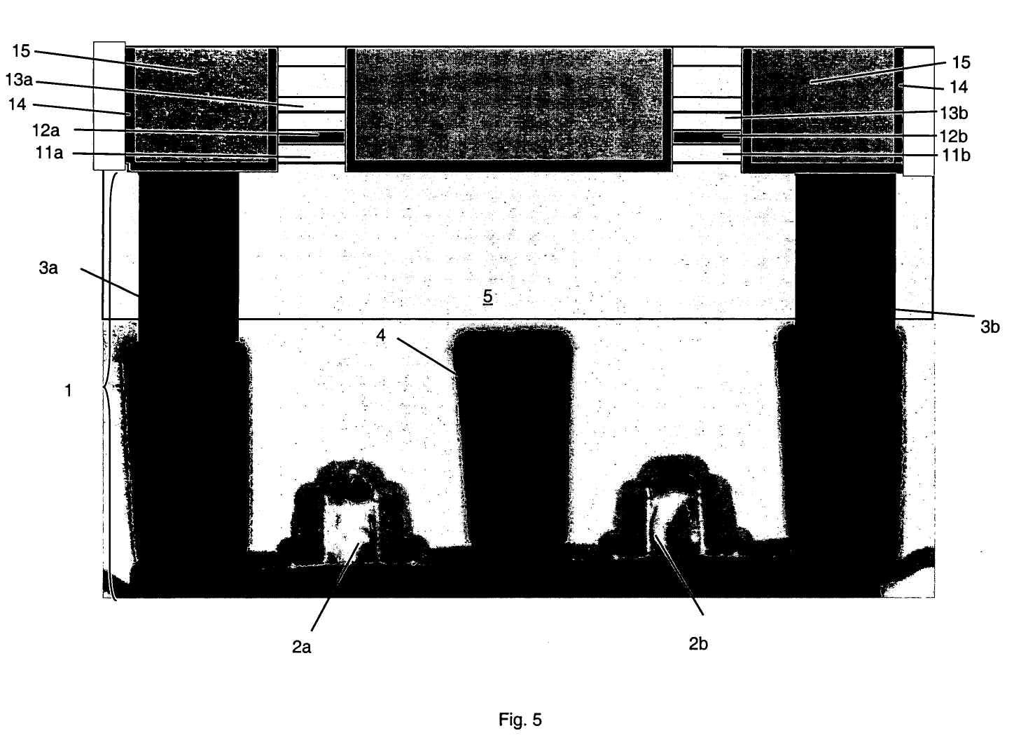

FIG. 5 represents the same view as in the previous figures after deposition of the layers forming the electrode contacts of the memory cells.

An optional, comparatively thin layer has been deposited which forms a liner 14. The liner 14 contacts the frontal faces of the volume of switching active material 12a, 12b. The purpose of this liner is to improve the thermal insulation of and to electrically couple to the volumes of switching active material. A suitable material for this liner 14 may be Ti or TiN which has a comparatively low thermal and electrical acceptable conductivity.

As the processing of Ti or TiN is significantly more complex and expensive when compared to the processing of tungsten as conventionally used, the thickness of the liner 14 is chosen to be comparatively low. That is, the thickness of this layer is chosen so that the favourable properties appear while at the same time the expenses of the complex and expensive processing are kept to a minimum.

In a variation—not shown—the liner 14 can be applied to the surfaces of the volumes of the switching material only, that is without covering the floor of the vias. In this way the properties of the liner material come into effect at the contact interface to a volume of switching active material only.

After the optional liner layer 14 has been deposited a layer 15 of tungsten or any suitable material for forming an electrode contact is deposited. This layer 15 fills the gaps still existing between the volumes of switching active material 12a, 12b and can be deposited using conventional CVD or physical vapour deposition (PVD) method process.

As mentioned before, the liner 14 is optional and can be omitted without leaving the scope of this invention. In this case the layer 15 of tungsten or any suitable material for forming an electrode contact is deposited directly onto the surface of the wafer thus filling the vias. As a consequence of omitting the thermally insulating liner layer 14 the thermal behaviour of a memory cell is degraded thus resulting in higher current values necessary for heating a piece of switching active material 12a, 12b.

As can be seen from the drawing and as mentioned before with respect to the vias, the upper end of a contact exceeds the upper edge of the coupled switching active material 12.

After depositing the layer 15 the surface of the chip is planarized as a preparation for the next processing, for example by using a conventional chemical-mechanical-polishing (CMP) process. The planarization process can be stopped when the state as illustrated in the drawing is reached, that is when the electrode contact material is removed from the surface of the insulating material covering the volumes of switching active material 12a, 12b.

In these aforementioned process the volumes of switching active material have been formed. The interface surfaces for coupling a volume of switching active material 12a, 12b to an electrode are perpendicular to the surface of the substrate 1, that is vertical, and have been produced in a single process step after the switching active material has been deposited.

Subsequently both the electrode contacts 16 have been formed, wherein the electrode contacts 16 electrically couple to the volumes of switching active material 12a, 12b of memory cells.

In this exemplary embodiment the electrode contacts 16a, 16c connect a volume of switching active material 12a, 12b to a transistor contact 3a, 3b. In contrast to that the electrode contact 16b connects two abutted interfaces of the volumes of switching active material to a connector 17, which further couples to another line, e.g. a bit line as will be explained in detail below.

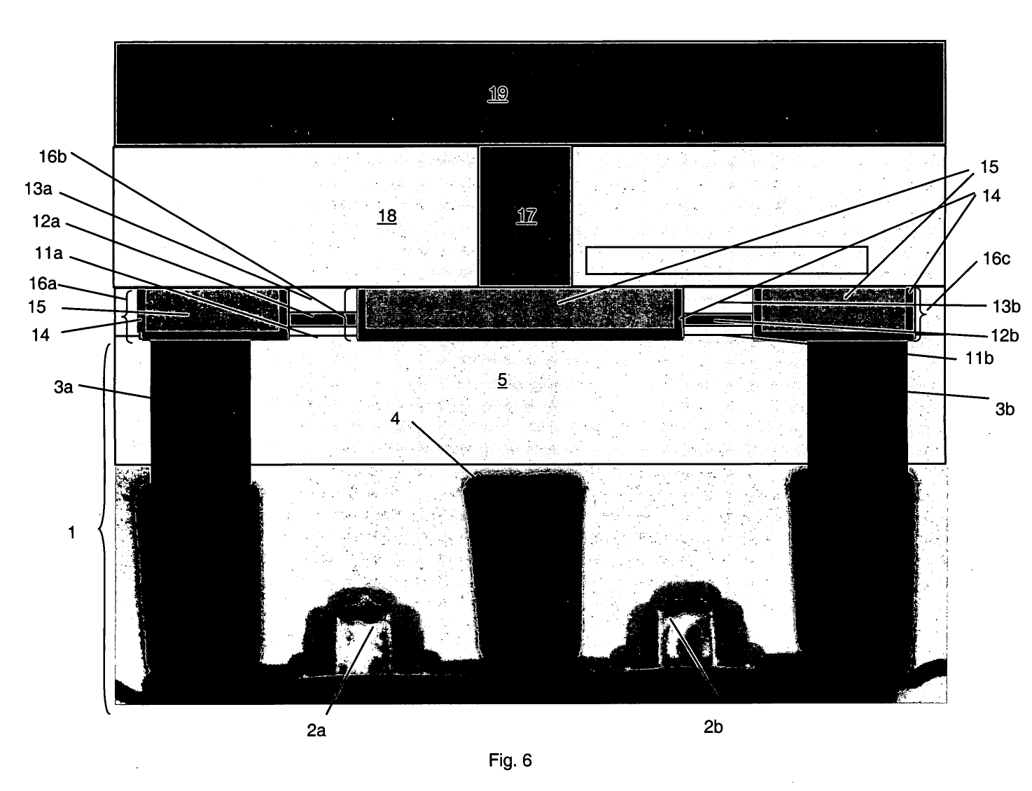

In FIG. 6 the results of the last processing are represented. That is in a subsequent step, an insulating layer 18 is deposited which covers and electrically insulates the elements below and with which a planar surface can be achieved. Subsequently, a via for connector 17 is formed using a conventional subsequent lithographic and etching process. The etching process must extend until baring the contacts 16 and be stopped at the latest before the surface active material 12 is reached. Then a layer of conducting material, e.g. tungsten, is deposited onto insulating layer 18 by using a conventional method, such as CVD, and planarized by a suitable planarization technique such as CMP. The connector 17 connects to the electrode contact 16b to form an electrical connector between the electrode contact 16b and a subsequent line.

In a further subsequent step a further connecting line 19 can be placed on top of the insulating layer 18 and the top surface of the connector 17 respectively. The connecting line 19 may be formed from any suitable metal using conventional method processes such as a CVD or PVD process to deposit the material and subsequently shaping the deposited layer using a conventional lithographic and etching process.

Summarizing the afore described processes, a method is disclosed to form volumes or lines of switching active material being horizontally—in the direction into the paper plane—and vertically embedded in insulating material, and wherein in one subsequent step the surfaces for both electrode contacts are formed using a single etching process to form vias assigned for being filled up with contact material, so that the contacts vertically extent the volumes of switching active material. Thus a method is disclosed wherein the contact surfaces and the contacts are formed after the switching active material is deposited.

The single etching process for forming the vias for the contacts allows to minimize overlay tolerances, so that the memory cell area can be shrunk to the minimum feature size (8F2 to 6F2).

Further on, the interfaces to the electrode contacts are on opposite front surfaces of the volumes of switching active material, so that the path of the current flow is straight-lined thus reducing parasitic resistances.

Furthermore the described method does not require additional method processes compared to the production process of a conventional memory cell of the bridge type and can be performed on top of a substrate as described with reference to FIG. 2, wherein the substrate has been formed conventionally.

Lastly it is to be mentioned that the chip containing the memory cells produced according to the described method processes is subject of further processing, e.g. additional wiring of the cells etc is needed.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of forming a memory device with a plurality of memory cells on top of a substrate, wherein the substrate provides first contacts for coupling a memory cell to a selection transistor, each memory cell comprising a volume of switching active material, the method comprising:
depositing a first layer of insulating material on the substrate;
depositing a layer of switching active material on the layer of insulating material;
patterning the layer of switching active material to form volumes of switching active material;
depositing a second layer of insulating material;
forming vias in the layers of the first insulating material, the switching active material and the second layer of insulating material in one method process; and
filling the vias with a conductive material to form first and second electrode contacts for electrically coupling the volumes of switching active material.

2. The method of claim 1, comprising forming a first electrode contact on top of a first contact provided in the substrate to couple one volume of switching active material to a first contact provided in the substrate.

3. The method of claim 1, wherein each electrode contact coupled to a bitline is formed between two adjacent volumes of switching active material to form a shared second electrode contact of the two adjacent volumes of switching active material.

4. The method of claim 1, further comprising forming an electrode contact on top of the second electrode contacts to couple the second electrode contact to a bit line.

5. The method of claim 1, further comprising depositing a hardmask layer on top of the layer of switching active material, the hardmask layer being etched in the same method process when etching the switching active material to form the volumes of switching active material.

6. The method of claim 1, further comprising depositing a hardmask layer on top of the second layer of insulating material, the hardmask layer being etched in the same method process when etching the vias.

7. A method of forming a memory device with a plurality of memory cells on top of a substrate, wherein the substrate provides first contacts for coupling a memory cell to a selection transistor, each memory cell comprising a volume of switching active material, the method comprising:
depositing a first layer of insulating material on the substrate;
depositing a layer of switching active material on the layer of insulating material;
patterning the layer of switching active material to form volumes of switching active material;
depositing a second layer of insulating material;
forming vias in the layers of the first insulating material, the switching active material and the second layer of insulating material in one method process;
depositing a layer of an electrically conductive, thermally isolating material on the substrate; and
depositing a layer of an electrically conductive material on the substrate to fill the gaps between the volumes of switching active material and to form first and second electrode contacts for electrically coupling the volumes of switching active material.

8. The method of claim 7, wherein the electrically conductive, thermally isolating material is Ti or TiN and wherein the material of the electrically conductive material to fill the gaps is tungsten.

9. The method of claim 7, comprising forming a first electrode contact is formed on top of a first contact provided in the substrate to couple one volume of switching active material to a first contact provided in the substrate.

10. The method of claim 8, comprising forming each electrode contact coupled to a bitline is formed between two adjacent volumes of switching active material to form a shared second electrode contact of the two adjacent volumes of switching active material.

11. The method of claim 8, further comprising forming an electrode contact on top of the second electrode contacts to couple the second electrode contact to a bit line.

12. The method of claim 8, further comprising depositing a hardmask layer on top of the layer of switching active material, the hardmask layer being etched in the same method process when etching the switching active material and the first insulating layer to form the volumes of switching active material.

13. The method of claim 8, further comprising depositing a hardmask layer on top of the second layer of insulating material, the hardmask layer being etched in the same method process when etching the vias.

14. A method for forming a memory device comprising:
defining a plurality of memory cells on a substrate defining a reference plane, wherein a memory cell comprises a volume of switching active material and electrodes for coupling to the volume at interfaces; and
forming the interfaces for coupling the volume of switching active material are formed after the switching active material has been deposited.

15. The method of claim 14, wherein the interface is perpendicular to the reference plane.

16. The method of claim 15, comprising forming the interfaces of a memory cell in a single etching step.

17. A memory device with a plurality of memory cells on a substrate defining a reference plane, each memory cell comprising:
means for providing a volume of switching active material having interfaces and electrodes for coupling to the volume at interfaces, the surface-normal of the interfaces being parallel to the reference plane, and wherein in the perpendicular direction to the reference plane the extent of the electrodes exceeds the extent of the interfaces of the volume of switching active material.

18. The memory device of claim 17, wherein the interfaces are perpendicular to the reference plane.

19. The memory device of claim 17, wherein a layer of thermally insulating, electrically conducting material is placed between the contact interfaces of an electrode and the volume of switching active material.

20. The memory device of claim 19, wherein the layer of thermally insulating, electrically conducting material is of titanium (Ti) or titanium nitride (TiN).

21. A memory device with a plurality of memory cells on a substrate defining a reference plane, each memory cell comprising:
a volume of switching active material having interfaces and electrodes for coupling to the volume at interfaces, the surface-normal of the interfaces being parallel to the reference plane, and wherein in the perpendicular direction to the reference plane the extent of the electrodes exceeds the extent of the interfaces of the volume of switching active material.
